(19) United States
(12) Patent Application Publication
(10) Pub. No.: US 2003/0101573 A1
(43) Pub. Date: Jun. 5, 2003

(54) Method for manufacturing a planar temperature sensor

(76) Inventors: Charles Scott Nelson, Clio, MI (US); Paul Casey Kikuchi, Fenton, MI (US); James Paul Vargo, Swartz Creek, MI (US); Douglas James Behrendt, Linden, MI (US)

Correspondence Address: VINCENT A. CICHOSZ, DELPHI TECHNOLOGIES, INC., Legal Staff, Mail Code: 480-414-420, P.O. Box 5052, Troy, MI, 48007-5052, US

(21) Appl. No.: 10/004,679

(22) Filed: Dec. 4, 2001

(51) Int. Cl. H01C 7/02; H01C 7/04; G01R 1/00; B23K 26/14

(52) U.S. Cl. 29/612; 29/620; 29/593; 219/121.68

(57) ABSTRACT

A method for manufacturing a planar temperature sensor including disposing a thick amount of a material having a temperature coefficient of resistance of greater than about 800 parts per million and a natural resistance of above about 5 micro-ohm-centimeters on a substrate, measuring a resistance value of said material, and setting a laser trimming device to ablate material consistent with achieving an inputted resistance value.

### BACKGROUND

This disclosure relates to temperature sensors. More particularly, the disclosure relates to a method for manufacturing a planar temperature sensor.

Planar temperature sensors are used in a wide variety of applications across many different disciplines. Such sensors require that resistance values be above about 200 ohms which is achieved by creating an elongated narrow ribbon of material having certain resistance characteristics. Where planar temperature sensors are intended to be used in high temperature environments, i.e., environments where temperatures are often above 400° C., traditionally the sensors will be manufactured using extremely precisely controlled thin film screen printing techniques. In order to ensure that the elongated sensor trace of the planar temperature sensor has a resistance above about 200 ohms, the length, width and thickness of the sensor must be tightly controlled. The precisely controlled thin film technique has been used since it is the only known technique capable of producing high temperature sensors reliably in a manufacturing process. Although such temperature sensors can be produced with the thin film method it is expensive and troublesome with respect to the extremely precise control required of the printing technique.

### SUMMARY

The above-described and other features and advantages of the present invention will be appreciated and understood by those skilled in the art from the following detailed description, drawings, and appended claims.

A method for manufacturing a planar temperature sensor comprises disposing a thick amount of material, which has a coefficient of resistance of greater than about 800 parts per million and a natural resistance of above about 5 micro-ohm-centimeters, on a substrate. A measurement of the resistance value of the material disposed is then taken. The measured resistance value is input to a laser trimming device as well as a target resistance value. The laser device abates material in a desired pattern to achieve the inputted target resistance value.

### BRIEF DESCRIPTION OF THE DRAWINGS

FIG. 1 is an exploded perspective view of a substrate and a conductive material pad which is printed on the substrate;

FIG. 2 is a perspective schematic representation of a single unit substrate and pad being laser trimmed;

FIG. 3 is a top plan view of a planar temperature sensor having a serpentine configuration; and

FIG. 4 is a graphic representation of resistance change over time in a refiring process.

### DETAILED DESCRIPTION

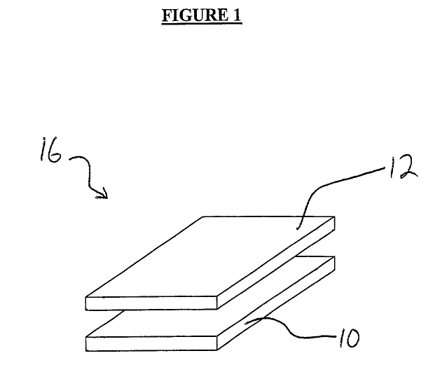

Referring to FIG. 1, in order to avoid the inherent difficulties of producing a precisely controlled thin film print of conductive material, the method disclosed herein employs a thick film deposition process or similar thick material deposition process either in the form of a pad on a substrate or a rough patterned configuration (not shown). The term thick film as used herein is considered to be material having a nominal thickness greater than or equal to about 2 micrometers in thickness. It is not important that the thickness be uniform over the entirety of the pad.

The method for manufacturing a planar temperature sensor for duty in a high temperature environment such as that above about 400° C. while avoiding the drawbacks inherent in using highly precisely controlled thin film printing techniques comprises depositing an amount of conductive material upon a substrate and configuring that material with a laser and refiring procedures.

A substrate material 10 referring to FIG. 1, may be a ceramic material such as alumina, for example, having a purity of 99.5%, zirconia, etc. and may be in a green state or in a prefired state at the time of deposition of a conductive material thereon. The conductive material 12 to be applied to substrate 10 is to include properties such as a high thermal coefficient of resistance (TCR) which for purposes of this disclosure is considered to be greater than about 800 parts per million (ppm); a high natural resistivity, which for purposes of this disclosure is considered to be greater than about 5 micro-ohm-centimeters and which resistivity is stable above 400° C.; and high stability over time meaning that repeatability is reliable over time in the greater than about 400° C. environment. Materials exhibiting such properties include but are not limited to, platinum, rhodium, titanium, palladium and mixtures and alloys comprising at least one of the foregoing materials.

The deposit may be simply in the form of a pad, as illustrated in FIG. 1 with numeral 12, or can be in a patterned form (not shown). In the event a patterned form is selected it is likely that a pattern approximating the desired final configuration of the sensor will be selected.

In the event a green substrate is employed, firing is desirable subsequent to the deposition process and before further processing. The components are fired at above about 1300° C. for a period of about three hours whereafter the materials are sufficiently free of organics to attain densification characteristics and are ready for further processing.

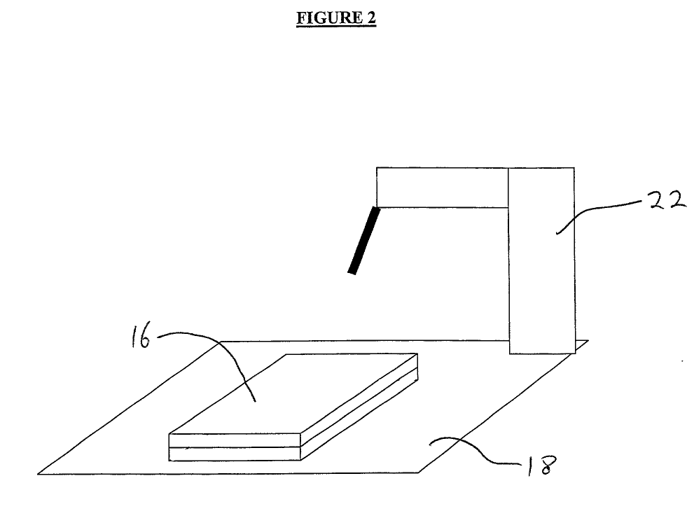

In the condition of the substrate and material illustrated in FIG. 1, the resistance in material 12 is generally about 2-3 ohms whereas the desired resistance in the sensor product is about 200 ohms at 0° C. With substrate 10 and material 12 (together referred to as unit 16) fired and ready for further processing, referring to FIG. 2, unit 16 is mounted to a fixture 18 in a laser trimming device 20; one example of a laser employed in this method is a diode-pumped Nd: YAG Laser which is a ubiquitously commercially available device. Device 20 includes sufficient control processing to allow the device to measure resistance in material 12 to within ±0.20% and accept a first desired resistance value. Device 20 then ablates material to meet the inputted valve.

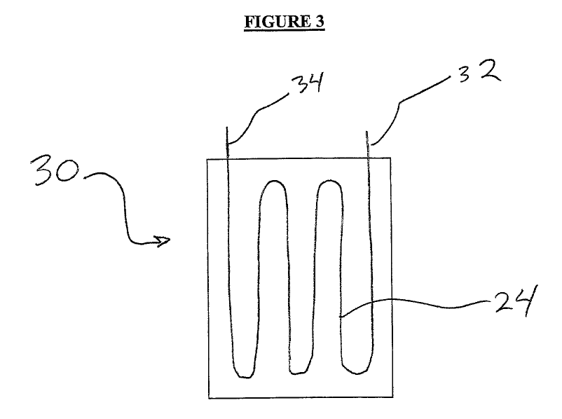

The device 20 is utilized to cut a pattern in material 12 having an elongated configuration such as a serpentine pattern (illustrated in FIG. 3) or a spiral pattern (not shown) or other elongated pattern as desired. The trimming process is employed to increase the resistance of material 12 to the inputted resistance value.

Because significantly more material is ablated in the process according to the method as disclosed herein, relative to the other laser trimming methods for devices employed in temperature environments below 200° C., significantly more heat is absorbed by unit 16. One of skill in the art will recognize that laser ablation on the order of 100 mm of material is unusually large and will generate significant quantities of heat. Because of the heating of unit 16, the method requires compensation with respect to the degree of desired ablation of material 12 with laser 22. More particularly, compensation for thermal change in the resistance of material 12 is accomplished by determining a resistance overshoot and adjusting the trimming process according thereto. Resistance overshoot is a function of the thermal coefficient of resistance of material 12, the target resistance, and the temperature rise during ablation. Resistance overshoot is represented, for example, by the following equation:

Resistance overshoot=TCR×Target Resistance×Temperature Rise;

where:

TCR=Thermal Coefficient of Resistance,

Target Resistance=Desired resistance of material 12, and

Temperature rise=fₙ(Pulse Duration, Pulse Frequency, Laser Power, Path Length, Step Size, Specific Heat of Substrate, and Mass).

The temperature rise is a function of: pulse duration, pulse frequency, and power of the laser; path length and step size; specific heat, mass, and thermal conductivity of substrate 10; and thickness and abated particle size of material 12. Temperature rise is represented, for example by the following equation:

Temperature Rise=A(Pulse Duration×Pulse Frequency×Laser Power×Path Length/Step Size)/(Specific Heat of Substrate×Mass),

where,

A=a constant determined empirically for a particular sensor material as fn(Thermal Conductivity of Substrate, Ink Thickness, and Ink Abated Particle Size).

The mentioned parameters are measured during trimming, the resistance overshoot is determined, and the trimming process is adjusted accordingly to compensate for the thermal change in the resistance of material 12 such that the desired resistance value is realized.

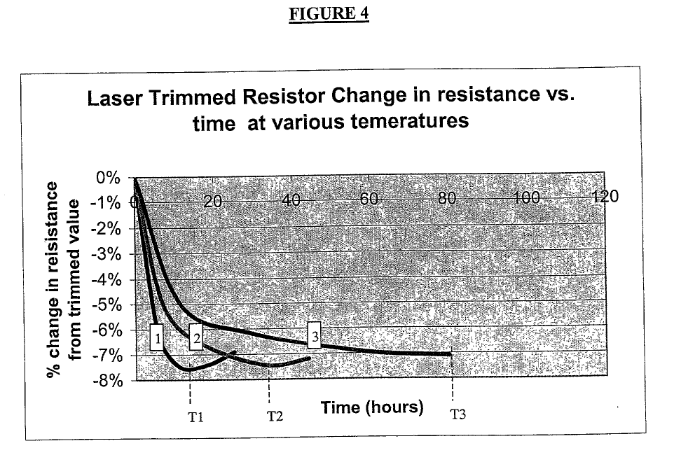

Following the first trimming operation, unit 16 is refired to smooth jagged edges and burn out small particles left from previous processing. The refiring process reduces resistance by about 5%. Refiring is achieved by subjecting unit 16 to an elevated temperature of about 1000° C. to about 1600° C. for about fifteen hours. In one embodiment, a selected temperature is maintained for a period of time commensurate with an inflection in a plot where the Y-axis is resistivity and the X-axis is time, as illustrated in FIG. 4. Resistivity decreases with time until an inflection point is reached, after which resistance will rise due to vaporization of the material 12. A first firing temperature 1, for example, is utilized until an inflection point is reached at T1. Firing temperatures are generally about 1100-1300° C. Determination of the exact point of inflection is made by monitoring resistance at a particular set point. Vaporization of material 12 is difficult to control leading to the teaching herein to terminate the refiring process at the point of inflection on the relevant curve, indicated by selected refiring temperature.

After refiring unit 16 is subjected in device 20 to a fine trimming process in which a further amount of material 12 is ablated, if necessary, in order to obtain the desired resistance value in view of resistivity lost during refiring or to otherwise enhance the first trimming.

Following the refiring and fine trimming processes, unit 16 is hermetically sealed in any number of ways including by glass passivation, for example, using alumina. The hermetic seal protects unit 16 against degradation of material 12 caused over time by, for example, oxidation, and reduces error by preventing the occurrence of catalytic reactions which produce localized heat that would otherwise undesirably affect resistance readings of unit 16.

Referring to FIG. 3, a top plan view of a finished planar temperature sensor employing a serpentine configuration 24 of material 12 is illustrated. The configuration, achieved pursuant to the disclosed method provides greater than 98% of total resistance of sensor 30 in configuration 24 while the balance of resistance is in leads 32, 34.

The method herein disclosed avoids the need for tightly controlled screen printing techniques for manufacturing sensors. Further, the method allows immediate resistance feedback and adjustment in a cost effective and simple system.

While preferred embodiments have been shown and described, various modifications and substitutions may be made thereto without departing from the spirit and scope of the invention. Accordingly, it is to be understood that the present invention has been described by way of illustration only, and such illustrations and embodiments as have been disclosed herein are not to be construed as limiting the claims.

What is claimed is:

1. A method for manufacturing a planar temperature sensor comprising:
disposing a thick amount of a material having a temperature coefficient of resistance of greater than about 800 parts per million and a natural resistance of above about 5 micro-ohm-centimeters on a substrate;
measuring a resistance value of said material; and
setting a laser trimming device to ablate material consistent with achieving an inputted resistance value.

2. A method for manufacturing a planar temperature sensor as claimed in claim 1 wherein said disposing comprises depositing a thick film of material on said substrate in a thick film deposition process.

3. A method for manufacturing a planar temperature sensor as claimed in claim 1 wherein said measuring is to within ±0.2% total resistance value.

4. A method for manufacturing a planar temperature sensor as claimed in claim 1 wherein said setting includes a first setting to achieve a first inputted resistance value and a second setting to achieve a second inputted resistance value.

5. A method for manufacturing a planar temperature sensor as claimed in claim 4 wherein said method further comprises firing said planar temperature sensor between said first setting and said second setting.

6. A method for manufacturing a planar temperature sensor as claimed in claim 5 wherein said firing is maintained for a period of time.

7. A method for manufacturing a planar temperature sensor as claimed in claim 5 wherein said firing is maintained until an inflection in a resistance versus time curve is reached.

8. A method for manufacturing a planar temperature sensor as claimed in claim 1 wherein said disposing is depositing one of platinum, rhodium, titanium, palladium and mixtures and alloys comprising at least one of the foregoing.

9. A method for manufacturing a planar temperature sensor as claimed in claim 1 wherein said substrate is a ceramic material.

10. A method for manufacturing a planar temperature sensor as claimed in claim 9 wherein said ceramic material is one of alumina, zirconium and composition including at least one of the foregoing materials.

11. A method for manufacturing a planar temperature sensor as claimed in claim 5 wherein said firing is at a temperature from about 1000° C. to about 1600° C.
